(19) United States
(12) Patent Application Publication
(10) Pub. No.: US 2002/0043999 A1
(43) Pub. Date: Apr. 18, 2002

(54) Complementary passive analog logic

(76) Inventor: Jeffery C. Frazier, Stevensville, MD (US)

Correspondence Address: Rodger H. Flagg, Suite 500, 2121 Eisenhower Ave., Alexandria, VA, 22314, US

(21) Appl. No.: 09/977,328

(22) Filed: Oct. 16, 2001

Related U.S. Application Data
(60) Provisional application No. 60/240,854, filed on Oct. 17, 2000.

(51) Int. Cl. H03K 3/356

(52) U.S. Cl. 327/211

(57) ABSTRACT

Complementary passive analog logic (CPAL) devices and circuits involve low power characteristics, and have high speed integrated circuit technology that is analog in design yet mimics the low power characteristics of complementary metal oxide (CMOS) logic designs. CPAL acts like CMOS in a high or low logic clock condition, but is analog in nature when clocked. CPAL is a distributed charge pump that super-positions an analog transient on a digital bias voltage. The two add vectorially on the positive going clock pulse. Nominal direct current (DC) power supply voltage is approximately equal to the threshold voltage of an N-channel transistor. CPAL is completely synchronous in operation, and a virtual open circuit in a non-clocked more. This pertains to reducing the noise found today in most integrated circuits. The latch design is for circuits of approximately 1.2 microns, and multiple flip-flops are provided to recapture most of the lost energy in existing integrated circuit designs.

### FIELD OF THE INVENTION

The present invention relates to complementary passive analog logic circuits, elements, and processes. In particular, the present invention relates to complementary passive analog logic (CPAL) devices and circuits involving lower power characteristics, and having high speed integrated circuit technology that is analog in design yet mimics the low power characteristics of complementary metal oxide (CMOS) logic designs, to convert noise to productive energy.

### BACKGROUND OF THE INVENTION

The field of high speed integrated circuit technology is known. Various devices and circuits are known for analog logic devices and circuits involving lower power characteristics.

Also, devices and circuits are known for analog design.

U.S. Pat. No. 5,900,763 to Rahim teaches an integrated circuit that provides analog and digital circuitry on a common substrate. It also teaches guard rings.

U.S. Pat. No. 6,038,181 to Braceias teaches a circuit for semiconductor devices that helps increase the speed of burn-in tests. The memory or logic devices under test are provided with a respective clock.

U.S. Pat. No. 5,920,210 to Kaplivisky teaches a digital interface circuit that has two inverters with different switching points in integrated circuits for low-to-high and high-to-low signal transitions in order to reduce throughput delay and thereby increase speed. It contains comparators that dissipate DC power.

U.S. Pat. No. 5,905,399 to Bosynak teaches a CMOS integrated circuit regulator for mixed mode integrated circuits, which reduces the digital switching noise by using dual source follower circuitry. In includes a charge reservoir bypass capacitor. The power supply switching noise is coupled directly to the n-substrate, which is shared by the analog circuitry.

U.S. Pat. No. 5,880,621 to Ohashi teaches an analog switch circuit that is composed of a p-channel transistor and an n-channel second transistor with connected drains.

U.S. Pat. No. 5,760,620 to Doluca teaches a CMOS-limited voltage swing device for reducing power during high frequency clocks. It contains a buffer or driver circuit that drives an output with a reduced voltage swing, and has a CMOS clock driver.

U.S. Pat. No. 6,064,251 to Park teaches a low voltage charge pump system with a large output voltage range. It includes PMOS transistors coupled to clock terminals.

U.S. Pat. No. 6,064,250 to Proesting teaches a low power adaptive charge pump. It includes an oscillator and a timing signal generator.

U.S. Pat. No. 6,046,675 to Merichelli teaches a charge pump for CMOS integrated circuits. It contains mirrored sections.

U.S. Pat. No. 6,028,473 to Kamei teaches a capacitor charge pump that uses a dynamic biasing circuit. The capacitors comprise MOS devices and includes a precharge circuit.

U.S. Pat. No. 6,057,707 to Scheicher teaches an integrated circuit that has a complex programmable logic device architecture.

U.S. Pat. No. 6,025,736 to Vora teaches a high-speed active ling switching technology using current mode logic for a high speed data path. It can use digital or analog circuitry.

U.S. Pat. No. 6,026,603 to Moore teaches charge pumping at low voltage to generate high voltage. It includes a capacitor and a secondary charge pump.

U.S. Pat. No. 6,041,322 to Meng teaches a digital artificial neural network that reduces memory requirements. It can use either digital or analog circuitry.

U.S. Pat. No. 5,010,512 to Hartstein teaches a neural network as MOSFET transistor elements. The network can be operated in a learning mode and an associative mode.

### SUMMARY OF THE INVENTION

The device according to the present invention provides complementary passive analog logic (CPAL) devices and circuits involving lower power characteristics, and having high speed integrated circuit technology that is analog in design yet mimics the low power characteristics of complementary metal oxide (CMOS) logic designs.

More particularly, in the present invention, CPAL acts like CMOS in a high or low logic clock condition, but is analog in nature when clocked. CPAL is a distributed charge pump that super positions an analog transient on a digital bias voltage. The two add vectorially on the positive going clock pulse. Nominal direct current (DC) power supply voltage is approximately equal to the threshold voltage of an N-channel transistor. CPAL is completely synchronous in operation, and a virtual open circuit in a non-clocked more.

This pertains to reducing the noise found today in most integrated circuits. This noise is wasted energy that the circuit could be using for productive purposes, but instead is lost and thus wasted. This invention recaptures the noise and converts it to productive energy. This latch design is for circuits of approximately 1.2 microns. Multiple latches will form a flip-flop and multiple flip-flops will form a shift register that can be used to recapture most of the lost energy in existing integrated circuit designs.

The latch design of the present invention, when embodied in an integrated circuit, provides positive cross coupled feedback utilizing simultaneous analog and digital signal processing, thus reducing the noise found in most integrated circuit designs.

Other objects and advantages of the present invention will be more readily apparent from the following detailed description when read in conjunction with the accompanying drawings.

### BRIEF DESCRIPTION OF THE DRAWINGS

FIG. 1 is a schematic circuit diagram of a latch according to the present invention.

FIG. 2 is a schematic circuit diagram of the substrate placement routing for the latch of FIG. 1.

FIG. 3 is a schematic circuit diagram of transistor placement, and the ground and voltage planes for the latch of FIG. 1.

FIG. 4 is a schematic circuit diagram of the latch substrate switching static transistor configuration.

FIGS. 5, 6, 7, and 8 show the latch operations during the various clock cycles.

### DETAILED DESCRIPTION OF THE INVENTION

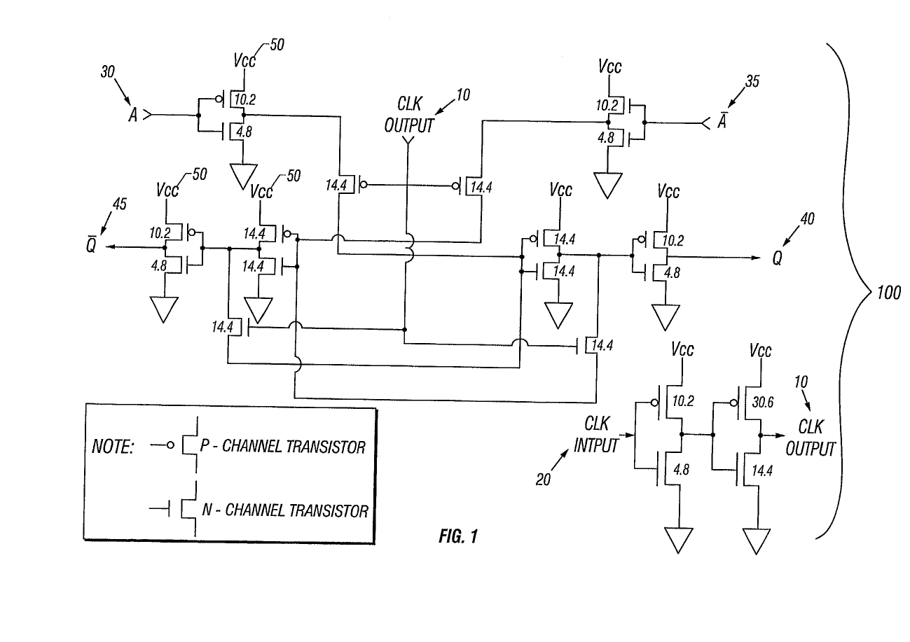

The circuitry shown in FIGS. 1-8 of the present invention provides complementary passive analog logic (CPAL) devices and circuits involving lower power characteristics, and having high speed integrated circuit technology that is analog in design yet mimics the low power characteristics of complementary metal oxide (CMOS) logic designs.

More particularly, in the present invention, CPAL acts like CMOS in a high or low logic clock condition, but is analog in nature when clocked. CPAL is a distributed charge pump that super-positions an analog transient on a digital bias voltage. The two add vectorially on the positive going clock pulse. Nominal direct current (DC) power supply voltage is approximately equal to the threshold voltage of an N-channel transistor. CPAL is completely synchronous in operation, and a virtual open circuit in a non-clocked mode.

This invention provides a means to reduce the noise found today in most integrated circuits. This noise is wasted energy that the circuit could be using for productive purposes, but instead is lost, and thus wasted. This invention recaptures the noise and converts it to productive energy. In an example embodiment, this latch 100 design is for circuits of approximately 1.2 microns, however this latch 100 design may be adapted by one of average skill in this art to higher or lower microns, depending upon its intended use, and such adaptations are intended to fall within the scope of this disclosure.

Multiple latches form a flip-flop function, and multiple flip-flop functions will form a shift register 88 that can be used to recapture most of the lost energy in existing integrated circuit 500 designs.

The latch 100 design of the present invention, when embodied in an integrated circuit 500, provides positive cross coupled feedback 600 utilizing simultaneous analog and digital 92, 93 signal processing 94, thus reducing the noise found in most integrated circuit 500 designs.

FIG. 1 is a schematic circuit diagram of a latch 100. The latch has inputs A and inverse A (30, 35), as well as outputs Q and inverse Q (40, 45). The circuit has voltages Vcc 50. A clock input 20 is provided at a clock circuit 2 to produce a clock output 10.

In FIG. 1, the circuit is constructed with p-channel transistors 62 and n-channel transistors 64. An exemplary gate-width 91 for each transistor 90 is shown in the drawings, and is based on its location and function.

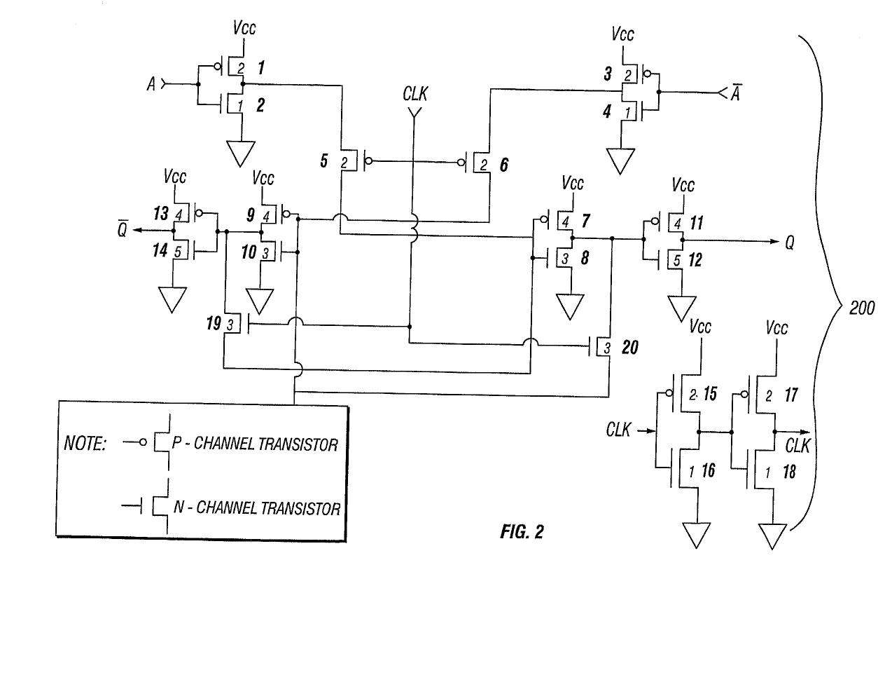

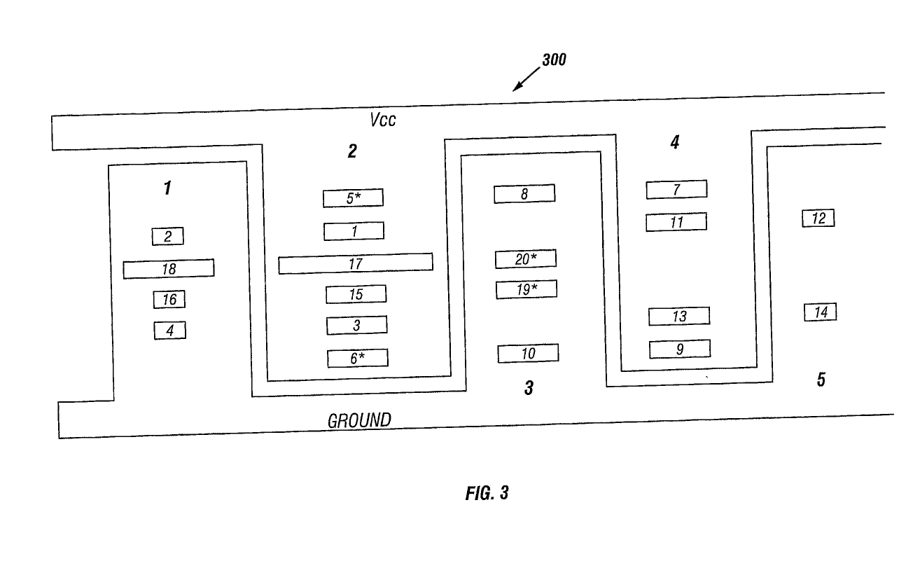

FIG. 2 shows the schematic circuit diagram of the substrate placement routing 200 for the latch 100 of FIG. 1. The numbered transistors 90 of this figure correspond to the placement chart shown in FIG. 3.

FIG. 3 shows the schematic circuit diagram of transistor placement 300, and the ground and voltage planes for the latch 100 of FIG. 1. The numbered transistors 90 of this figure correspond to the numbered transistors 90 shown and numbered correspondingly in FIG. 2.

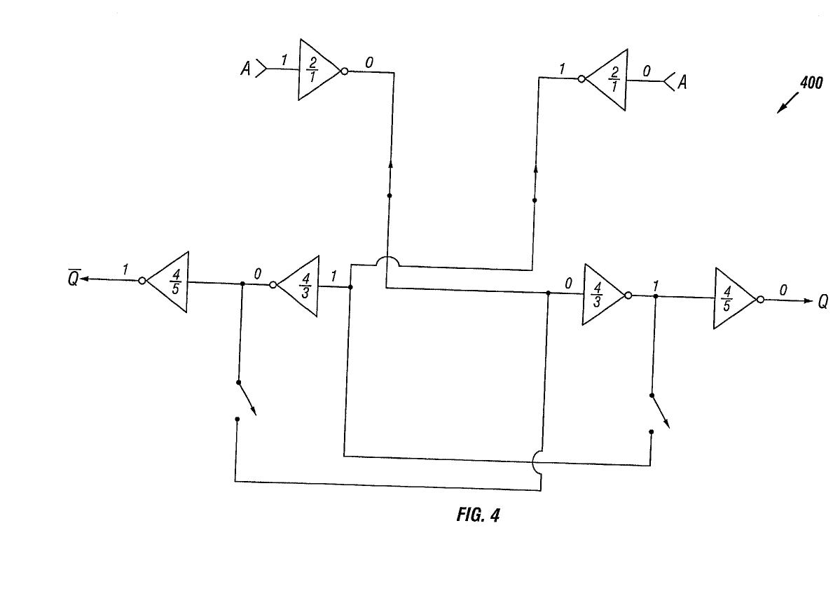

FIG. 4 shows the schematic circuit diagram of the latch 100 substrate switching static transistor configuration 400. Descriptive labels are provided for the transistors 90 shown, including the n-channel/p-channel substrate 1, clock 2, signal path 3, load data configuration 4, latch data configuration 5, direct current (D.C.) signal path 6, load input data configuration 7, 8. The substrate 4 A.C. references to substrate 2. Substrate 9 is the substrate 3 A.C. referenced to substrate 1; and substrate 10 is substrate 5 A.C. referenced to substrate 3.

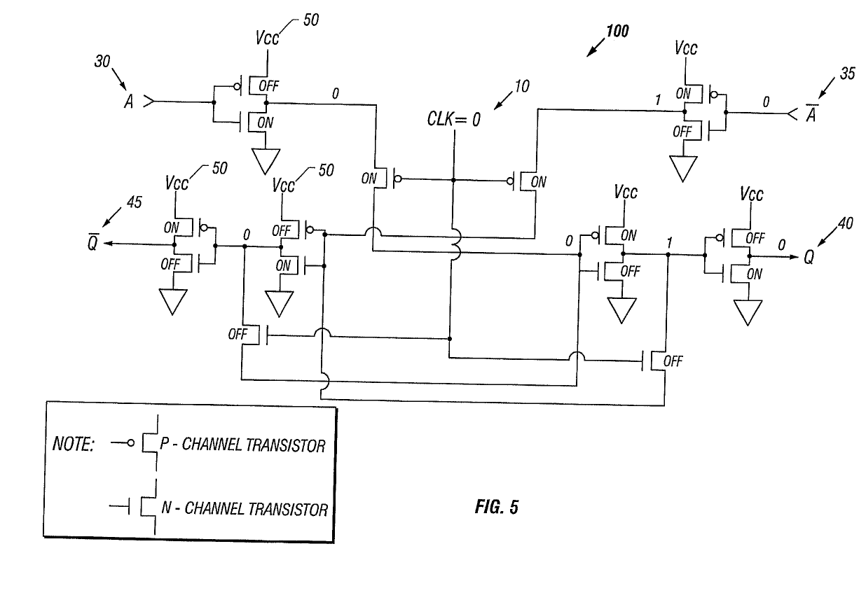

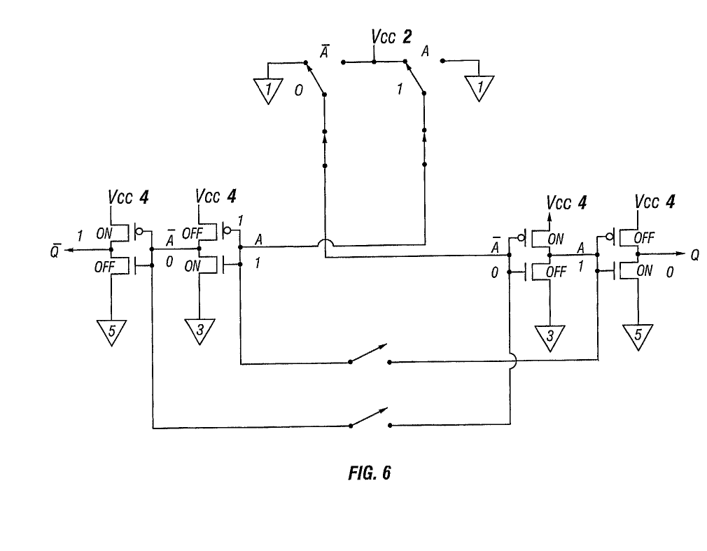

FIGS. 5, 6, 7, and 8 show the latch 100 operations during the various clock 2 cycles. In FIG. 5, there is no D.C. current path between Vcc A 53 and Vcc D 56. No D.C. current path exists between GND C and GND C, E, and the circuit is charging 76. In FIG. 6, showing a static model, the CLK is low, the circuit is charging 76, there is no D.C. current path between Vcc B 54 and Vcc D 56, and there is no D.C. current path between GND A 57 and GND C and GND E.

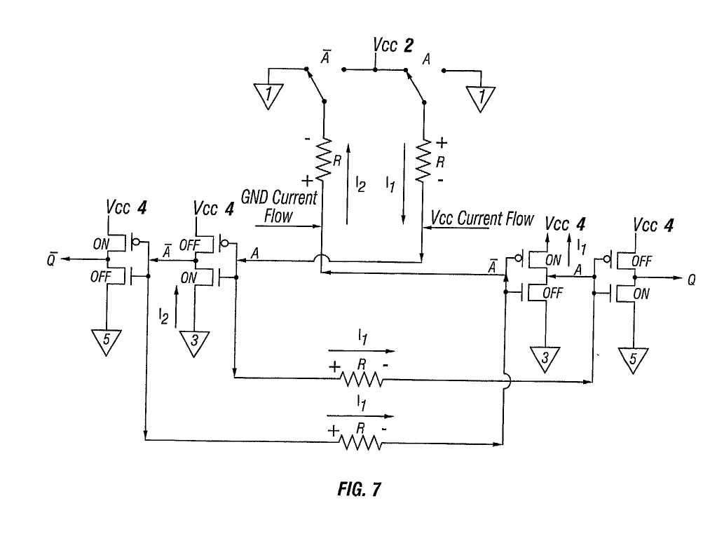

FIG. 7 is a static model showing the latch 100 operations during one of the various clock 2 cycles. In this figure, the clock 2 is rising from GND 49 to voltage Vcc 50.

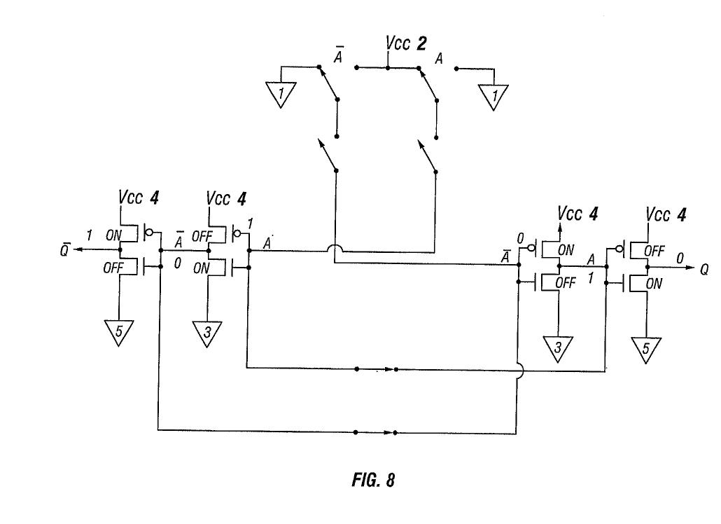

FIG. 8 is a static model showing the latch 100 operations during one of the various clock 2 cycles. In this figure, the integrated circuit 500 is discharged, no D.C. current flows, Vcc B 54 is shorted to Vcc D 56, GND A 57 is shorted to GND C and GND E, the clock 2 is logic Vcc A 53, and no D.C. current paths exists between Vcc B 54 and Vcc D 56.

The invention being thus described, it will be evident that the same may be varied in many ways. Such variations are not to be regarded as a departure from the spirit and scope of the invention and all such modifications are intended to be included within the scope of the claims.

What is claimed is:

1. A complimentary passive analog logic apparatus with low power characteristics to convert lost energy to productive energy, which comprises:
a) multiple latches positioned to form a flip-flop circuit,
b) a plurality of said flip-flop circuits positioned to form a shift register;
c) a distributed charge pump that super positions an analog transient signal on a digital bias voltage;
d) said shift register configured to provide a positive cross coupled feedback utilizing simultaneous analog and digital signal processing to recapture most of the lost energy in the form of unwanted noise, and said complimentary passive analog logic apparatus converts said lost energy to productive energy.

2. The apparatus of claim 1, wherein said multiple latches are selected to be for circuits of approximately 1.2 microns.

3. The apparatus of claim 1, wherein the complementary passive analog logic apparatus incorporates high speed integrated analog circuit technology which mimics the low power characteristics of complementary metal oxide logic designs.

4. The apparatus of claim 1, wherein the analog transient signal and the digital bias voltage are added vectorially on the positive going clock pulse.

5. The apparatus of claim 1, wherein the nominal direct current power supply voltage is approximately equal to the threshold voltage of an N-channel transistor.

6. The apparatus of claim 1, wherein the multiple latches provide positive cross coupled feedback utilizing simultaneous analog and digital signal processing.

7. The apparatus of claim 1, wherein the complimentary passive analog logic apparatus, further comprises an n-channel substrate, a p-channel substrate, a clock signal, a signal path, a load data configuration, a latch data configuration, and a direct current (D.C.) signal path.

8. The apparatus of claim 1, wherein the complimentary passive analog logic apparatus is synchronous in operation to provide a virtual open circuit in a non-clocked mode.

9. A complimentary passive analog logic apparatus with low power characteristics, which comprises:
a) a distributed charge pump super positions an analog transient signal and a digital bias voltage, which are added vectorially to a positive going clock pulse;
b) multiple latches positioned to form a flip-flop circuit,
c) multiple flip-flop circuits positioned to form a shift register; and
d) said shift register is configured to provide a positive cross coupled feedback utilizing simultaneous analog and digital signal processing to recapture most of the lost energy in existing integrated circuit design, said complimentary passive analog logic apparatus substantially converts said lost energy in the form of unwanted noise to productive energy.

10. The apparatus of claim 9, wherein said multiple latches are selected to be for circuits of approximately 1.2 microns.

11. The apparatus of claim 9, wherein the complementary passive analog logic apparatus incorporates high speed integrated analog circuit technology which mimics the low power characteristics of complementary metal oxide logic designs.

12. The apparatus of claim 9, wherein the nominal direct current power supply voltage is approximately equal to the threshold voltage of an N-channel transistor.

13. The apparatus of claim 9, wherein the multiple latches provide positive cross coupled feedback utilizing simultaneous analog and digital signal processing.

14. The apparatus of claim 9, wherein the complimentary passive analog logic apparatus with low power characteristics, further comprises an n-channel substrate, a p-channel substrate, a clock signal, a signal path, load data configuration, latch data configuration, and a direct current (D.C.) signal path.

15. The apparatus of claim 9, wherein the complimentary passive analog logic apparatus is synchronous in operation to provide a virtual open circuit in a non-clocked mode

16. A complimentary passive analog logic apparatus with low power characteristics to recapture lost energy in the form of unwanted noise, which comprises:
e) a distributed charge pump that super positions an analog transient signal and a digital bias voltage, which are added vectorially on a positive going clock pulse;
f) multiple latches positioned to form a flip-flop circuit,
g) multiple flip-flop circuits positioned to form a shift register;
h) the complimentary passive analog logic apparatus further comprises an n-channel substrate, a p-channel substrate, a clock signal, a signal path, load data configuration, latch data configuration, and a direct current (D.C.) signal path; and
i) said shift register is configured to provide a positive cross coupled feedback utilizing simultaneous analog and digital signal processing to recapture most of the lost energy in the form of unwanted noise, found in most existing integrated circuit design, and said complimentary passive analog logic apparatus thereby substantially converts said lost energy to productive energy.

17. The apparatus of claim 16, wherein said multiple latches are selected to be for circuits of approximately 1.2 microns.

18. The apparatus of claim 16, wherein the complementary passive analog logic apparatus incorporates high speed integrated analog circuit technology which mimics the low power characteristics of complementary metal oxide logic designs.

19. The apparatus of claim 16, wherein the nominal direct current power supply voltage is approximately equal to the threshold voltage of an N-channel transistor.

20. The apparatus of claim 16, wherein the multiple latches provide positive cross coupled feedback utilizing simultaneous analog and digital signal processing, and the complimentary passive analog logic apparatus is synchronous in operation to provide a virtual open circuit in a non-clocked mode.
